(19) United States
(12) Patent Application Publication
(10) Pub. No.: US 2023/0178581 A1
(43) Pub. Date: Jun. 8, 2023

(54) BSI IMAGE SENSOR AND MANUFACTURING METHOD THEREOF

(71) Applicant: WUHAN XINXIN SEMICONDUCTOR MANUFACTURING CO., LTD., Wuhan (CN)

(72) Inventors: Zhenya LI, Wuhan (CN); Peng WANG, Wuhan (CN); Yujiao FANG, Wuhan (CN); Lu ZHOU, Wuhan (CN)

(21) Appl. No.: 17/646,662

(22) Filed: Dec. 30, 2021

(30) Foreign Application Priority Data
Dec. 8, 2021 (CN) 202111512451.X

(51) Int. Cl. H01L 27/146

(52) U.S. Cl. CPC H01L 27/1464; H01L 27/14685; H01L 27/14636

(57) ABSTRACT

The present application relates to a BSI image sensor and a method of forming same. The method of forming a BSI image sensor including providing a pixel substrate having a front side and an opposing backside; depositing a titanium nitride layer over the backside of the pixel substrate using a PVD process; depositing a tungsten film on a surface of the titanium nitride layer using a CVD process; and etching the tungsten film and the titanium nitride layer to form a tungsten grid on the backside of the pixel substrate. The method of present application enables to grow a tungsten film having a good uniformity, a superior flatness and an reduced risk of tungsten loss.

### CROSS-REFERENCE TO RELATED APPLICATION

This application claims the priority of Chinese patent application number 202111512451.X, filed on Dec. 8, 2021, the entire contents of which are incorporated herein by reference.

### TECHNICAL FIELD

The present application relates to the field of semiconductor technology, and more particularly, to a backside illuminated (BSI) image sensor and a method of forming same.

### BACKGROUND

CMOS image sensor has become mainstream image sensor for the camera is thanks to its high sensitivity, wide dynamic range, high resolution, low power consumption, flexible image capture capability and excellent system integration. Compared to front side illuminated (FSI) image sensors, backside illuminated (BSI) image sensors (referred to hereinafter as “BSI image sensors”) can acquire more radiation energy per pixel within the same unit of time, which can result in a significantly increased image quality. Therefore, BSI technology raises the imaging sensitivity of CMOS image sensors to a new level.

Due to its good light-shielding properties, the metal tungsten is often used to fabricate light shields (referred to hereinafter as “tungsten grids”) in the forming process of BSI image sensors (e.g., chips) for preventing light that is incident on a pixel region and intended for one pixel from diffusing into adjacent pixels as well as blocking light from entering into regions outside the pixel region that are desired to be optically dark.

However, insufficient flatness or even tungsten loss (W loss) occurred in the existing BSI image sensors affect their optical performances.

### SUMMARY

The present application provides a BSI image sensor and method of forming a BSI image sensor, in order to optimize the morphology of tungsten grid in the BSI image sensor and thus improve optical performances of the BSI image sensor.

In one aspect, present application provides a method of forming a BSI image sensor, comprising the steps of:

providing a pixel substrate having a front side and an opposing backside, the pixel substrate comprising a plurality of conductive interconnects formed on the front side, an insulating layer formed on the backside and a plurality of light sensitive pixels configured to sense radiation that enters the pixel substrate from the backside;

depositing a titanium nitride layer over the backside of the pixel substrate using a physical vapor deposition (PVD) process, the titanium nitride layer covering the is insulating layer;

depositing a tungsten film on a surface of the titanium nitride layer using a chemical vapor deposition (CVD) process; and

etching the tungsten film and the titanium nitride layer to form a tungsten grid on the backside of the pixel substrate.

Optionally, the PVD process for depositing the titanium nitride layer uses a target having a titanium purity of 99.999% or higher and is performed at a DC power level of 6000-12000 W and a nitrogen flow rate of 50-100 sccm.

Optionally, the titanium nitride layer may have a thickness of 130-500 Å Optionally, prior to the deposition of the titanium nitride layer, the method further comprises:

etching the pixel substrate to form therein a plurality of through-holes extending from the backside to tops of the plurality of conductive interconnects;

forming an isolation layer over side walls of the through-holes;

forming a metallic adhesion layer, which is in geometric conformity over a top surface of the insulating layer, a surface of the isolation layer and bottoms of the through-holes;

depositing a conductive material on the metallic adhesion layer, wherein the deposited conductive material completely fills the through-holes and further covers a surface of the metallic adhesion layer; and

removing the conductive material and the metallic adhesion layer above top edges of the through-holes using a planarization process, the conductive material received in the through-holes constituting conductive pillars, wherein after the titanium nitride layer is deposited, the titanium nitride layer is in contact with the conductive pillars.

Optionally, the metallic adhesion layer is made of a material containing at least one of tungsten nitride and titanium nitride, and the conductive pillars are made of a material containing tungsten.

Optionally, the metallic adhesion layer and the conductive material are deposited using CVD processes.

Optionally, after the tungsten film is formed and before the tungsten film and the titanium nitride layer are etched, the method further comprise, forming a bonding pad material layer on the tungsten film and etching the bonding pad material layer, to form bonding pads that are electrically connected to the conductive pillars via the tungsten film and the titanium nitride layer.

Optionally, etching the tungsten film and the titanium nitride layer to form the tungsten grid on the backside of the pixel substrate comprises:

forming a protective layer on the tungsten film so that the protective layer covers an exposed surface of the tungsten film; and

forming a protective layer on the tungsten film, the protective layer covering an exposed surface of the tungsten film; and

forming a mask layer on the protective layer, patterning the mask layer using photolithography and etching processes and etching a stack constituted by the protective layer, the tungsten film and the titanium nitride layer using the patterned mask layer as a mask, thereby forming the tungsten grid on the backside of the pixel substrate.

Optionally, the insulating layer comprises, stacked one on another from the backside in a direction away from the front side, a high-k material film, a bottom oxide film, a nitride film and a top oxide film, and the top oxide film and the nitride film in the insulating layer are also patterned when the stack constituted by the protective layer, the tungsten film and the titanium nitride layer is etched to form the tungsten grid.

In another aspect, present application provides a BSI image sensor formed using the method as defined above. The BSI image sensor comprises:

a pixel substrate having a front side and an opposing backside, the pixel substrate comprising a plurality of conductive interconnects formed on the front side, an insulating layer formed on the backside, a plurality of light sensitive pixels configured to sense radiation that enters the pixel substrate from the backside, and a grid area;

a plurality of conductive pillars arranged outside the grid area, each of the plurality of conductive pillars extending through the pixel substrate and having one end electrically connected to a corresponding one of the plurality of conductive interconnects and the other end connected to a titanium nitride layer, the titanium nitride layer having a surface away from the conductive pillars covered by a tungsten film, each of the titanium nitride layer and the tungsten film extending to the grid area;

bonding pads arranged outside the grid area, the bonding pads disposed on a surface of the tungsten film away from the titanium nitride layer, the bonding pads electrically connected to the conductive pillars via the tungsten film and the titanium nitride layer; and

a tungsten grid arranged within the grid area, the tungsten grid comprising the titanium nitride layer and the tungsten film, which are stacked from the backside in a direction away from the front side.

In the forming method of BSI image sensors provided in present application, the tungsten grid is formed by depositing a titanium nitride layer using a PVD process to provide a tungsten growth surface having an extremely low roughness, depositing a tungsten film by a CVD process and etching the tungsten film and the titanium nitride layer. Since the tungsten growth surface is sufficiently flat, crystalline grains of tungsten in the tungsten film are relatively small, which enables the tungsten film to have a good uniformity and a superior flatness and allows to mitigate the risk of tungsten loss due to the occurrence of inter-crystalline corrosions. Thus, the resulting tungsten grid has an improved flatness and an optimized morphology, which are helpful in enhancing optical performances of the BSI image sensors.

In the BSI image sensor provided in present application, the tungsten grid has is good quality and morphology, which are helpful in obtaining superior optical performances.

### BRIEF DESCRIPTION OF THE DRAWINGS

FIG. 1 is a flowchart of a method of forming a BSI image sensor according to an embodiment of present application.

FIG. 2 is a schematic cross-sectional view of a pixel substrate used in the method of forming a BSI image sensor according to an embodiment of the present application.

FIGS. 3A to 3E schematically illustrate a process for forming conductive pillars in the pixel substrate in the method of forming a BSI image sensor according to an embodiment of present application.

FIG. 4 is a schematic cross-sectional view of a structure after formation of a titanium nitride layer in the method according to an embodiment of the present application.

FIG. 5 is a schematic cross-sectional view of a structure after the formation of the tungsten film in the method according to an embodiment of the present application.

FIGS. 6A and 6B are schematic cross-sectional views showing the formation of a tungsten grid in the method according to an embodiment of the present application.

In the figures,

100-pixel substrate; 100a-front side; 100b-backside; 110-conductive interconnection; 120-insulating layer; 200-support substrate; 10-through-hole; 101-isolation layer; 102-metallic adhesion layer; 20-conductive material; 130-conductive pillar; 103-titanium nitride layer; 104-tungsten film; 140-bonding pad; 105-protective layer; 150-tungsten grid; GA-grid area.

### DETAILED DESCRIPTION

In order to overcome the problem of insufficient flatness or even W loss of tungsten grids founded in existing backside illuminated (BSI) image sensors, inventors have found through research that, when depositing a tungsten film over a substrate layer using chemical vapor deposition (CVD), tungsten grows as columnar crystals and the quality of the resulting tungsten film is significantly affected by surface flatness of the substrate layer. If the tungsten is deposited on the substrate surface having a rough surface, then the tungsten crystals will grow to be large crystalline grains with non-uniform sizes, leading to inferior flatness of the resulting tungsten film. Conventionally, since the existing substrate layer (e.g., silicon oxide or tungsten nitride) is usually formed by CVD and often has high surface roughness, the tungsten film deposited thereon by CVD usually has poor surface flatness. Moreover, when patterning such a tungsten film to fabricate a tungsten grid, protective and mask layers over the tungsten film are also poor in flatness, leading to unsatisfactory quality of the resulting tungsten grid. Further, plasma used during etching processes and by-products therefrom tend to cause inter-crystalline corrosion in the tungsten film, which may lead to the deficiency of tungsten loss (W loss). All of these factors ultimately lead to poor morphology and quality of the resulting tungsten grid and hence go against optical performance of the BSI image sensor.

The BSI image sensor and the method provided in the present application will be described in greater detail below by way of specific examples with reference to the accompanying drawings. Advantages and features of the present application will become more apparent from the following description. Noted that the figures are provided in a very simplified form not necessarily drawn to exact scale for the only purpose of helping to explain the embodiments disclosed herein in a more convenient and clearer way. Also noted that the order of steps in the method as presented herein is not the only order in which these steps must be performed. Rather, some of the steps may be omitted, and/or other steps that are not described herein may be added.

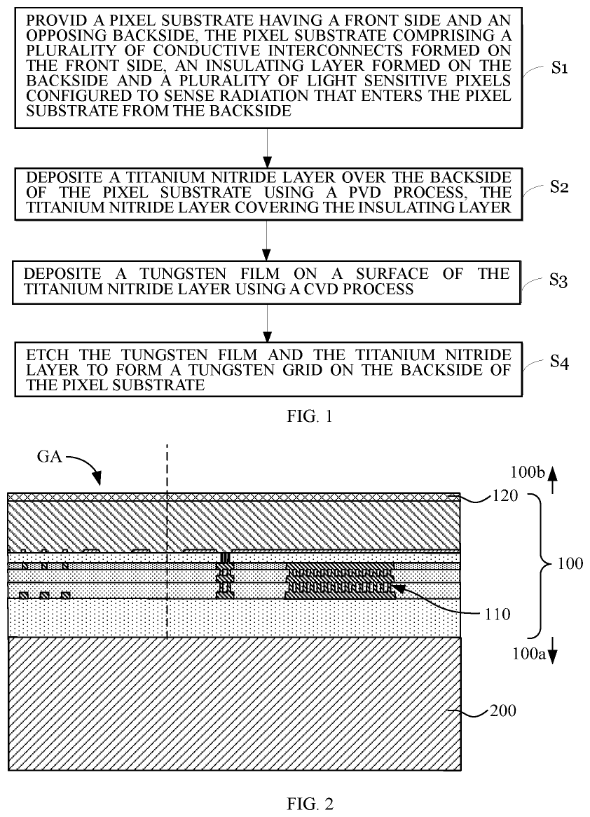

Referring to FIG. 1, embodiments of the present application relate to a method of manufacturing a BSI image sensor, which includes:

in a first step S1, providing a pixel substrate having a front side and an opposing backside, the pixel substrate comprising a plurality of conductive interconnects formed on the front side, an insulating layer formed on the backside and a plurality of light sensitive pixels configured to sense radiation that enters the pixel substrate from the backside thereof;

in a second step S2, depositing a titanium nitride layer over the backside of the pixel substrate using a physical vapor deposition (PVD) process, the titanium nitride layer covering the insulating layer;

in a third step S3, depositing a tungsten film on a surface of the titanium nitride layer using a chemical vapor deposition (CVD); and

in a fourth step S4, etching the tungsten film and the titanium nitride layer to form a tungsten grid on the backside of the pixel substrate.

The method will be described in greater detail below with reference to the accompanying drawings.

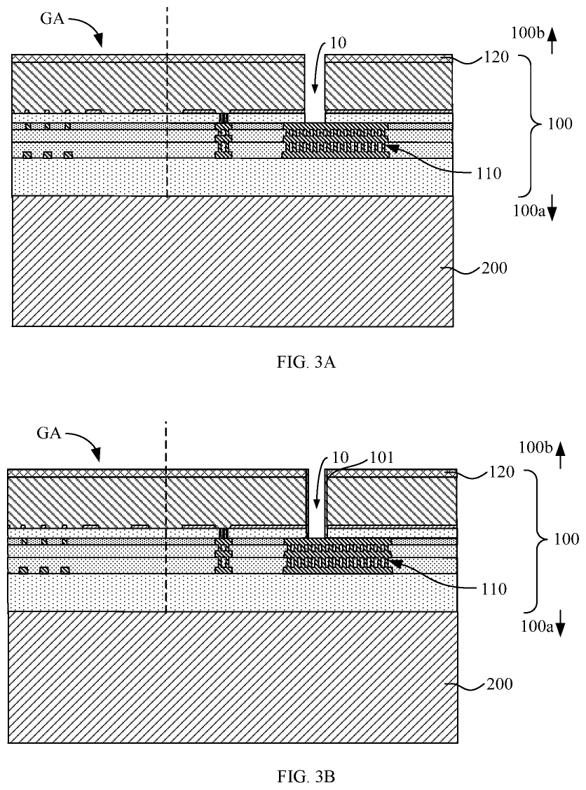

FIG. 2 is a schematic cross-sectional view of the pixel substrate used in the method of forming a BSI image sensor according to an embodiment of present application. Referring to FIG. 2, in the first step, the pixel substrate 100 having the front side 100a and the opposing backside 100b is provided. The pixel substrate 100 includes a plurality of conductive interconnects 110 formed on the front side 100a, and the insulating layer 120 formed on the backside 100b. The pixel substrate 100 includes a plurality of light sensitive pixels configured to sense radiation that enters the pixel substrate 100 from the backside 100b of the pixel substrate 100.

In order to facilitate the subsequent steps to be performed on the backside 100b, the pixel substrate 100 may be bonded to a support substrate 200 (e.g., by intermolecular forces or by an adhesive) at the front side 100a. Each of the pixel substrate 100 and the support substrate 200 may include silicon, germanium, silicon germanium, silicon carbide, gallium oxide, gallium arsenide, gallium phosphide, indium phosphide, indium arsenide, indium antimonide or any other suitable well-known material.

The pixel substrate 100 includes a grid area GA where the tungsten grid is arranged, and the grid area GA is configured to prevent light that is incident on a pixel region and intended for one pixel from diffusing into adjacent pixels and to block light from entering into regions which are desired to be optically dark and located outside the pixel region. As an example, the grid area GA includes the pixel region on the pixel substrate 100, where a plurality of light sensitive pixels are arranged; and regions surrounding the pixel region and configured to accommodate reference pixels, digital devices and other devices that are desired to be optically dark. The BSI image sensor to be manufactured according to this embodiment of the present application has a backside illuminated structure, i.e., incident light radiation enters the pixel substrate 100 from the backside 100b and is sensed at the front side 100a by pixels arranged within and on the front side 100a of the pixel substrate 100. All the pixels in the pixel region may include, for example, photodiodes. For the sake of simplicity, only part of the grid area is shown.

The plurality of conductive interconnects 110 are formed on the front side 100a of the pixel substrate 100 and may be electrically connected to the pixel and other devices in the grid area GA. The conductive interconnects 110 may be multi-layer electrically interconnecting structures each including a plurality of patterned conductive layers isolated by a dielectric material, and a plurality of conductive plugs. The conductive layers and plugs provide interconnection between various doped regions, circuits and inputs/outputs of the BSI image sensor. Seen from the backside 100b, each conductive interconnection 110 may have a top side facing toward the backside 100b of the pixel substrate 100, at which the conductive interconnection 110 may be electrically connected to the outside in subsequent steps. It is to be noted that the components and locations of the conductive interconnects 110 are shown merely as an example and may vary as actually needed.

It is to be noted that since the description of embodiments of the present application focuses on the formation of the tungsten grid on the backside 110b, it is assumed that in the first step of providing a pixel substrate 100, the pixel substrate 100 has subjected all the front side processes including those for forming the pixels and the conductive interconnects 110 and has been bonded to the support substrate 200. Moreover, in order to facilitate the lead-out of the electrical property of the conductive interconnects 110 from the backside 110b, the pixel substrate 100 may be thinned from the backside 110b, followed by the deposition of the insulating layer 120 thereon. The insulating layer 120 may include at least one of silicon oxide, silicon nitride, silicon oxynitride, silicon carbide, nitride-doped silicon carbide, high dielectric constant (i.e., high-k) materials (e.g., alumina, hafnium oxide, etc.) and other insulating materials. The insulating layer 120 may be either a single-layer structure or a compound structure consisting of multiple layers of materials. In this embodiment, the insulating layer 120 may be, for example, a compound insulating layer including, stacked one on another from the backside 110b of the pixel substrate 100 away from the pixel substrate 100, a high-k material film, a bottom oxide film, a nitride film and a top oxide film. The stack of the bottom oxide film, the nitride film and the top oxide film is referred to herein as an ONO stack.

Optionally, in one embodiment of present application, before the second step is carried out, a plurality of conductive pillars electrically connected to the conductive interconnects 110 are formed in the pixel substrate 100, so as to lead the electrical property of the conductive interconnects 110 to the backside 110b of the pixel substrate 100 via the conductive pillars, thereby facilitating the manufacture of bonding pads electrically connected to conductive interconnects 110 on the backside 100b in subsequent steps. Moreover, when the plurality of conductive pillars are formed in previous steps, the subsequently formed titanium nitride layer can be configured to contact the conductive pillars, and positions of bonding pads can be flexibly set according to the coverage area of the titanium nitride layer.

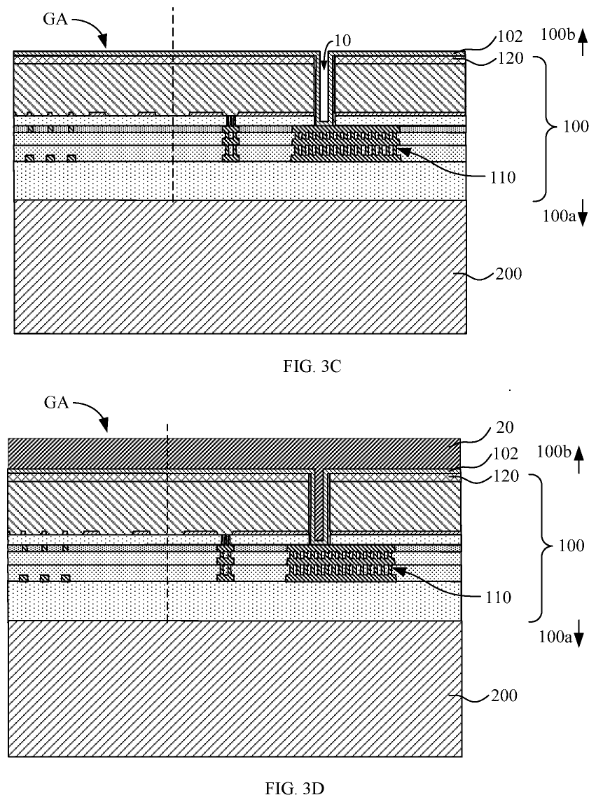

FIGS. 3A to 3E schematically illustrate a process for forming conductive pillars in is the pixel substrate in the method of forming a BSI image sensor according to an embodiment of present application. Referring to FIGS. 3A to 3E, as an example, prior to the deposition of the titanium nitride layer in the second step, the method of forming a BSI image sensor according to an embodiment includes the following steps:

At first, as shown in FIG. 3A, the pixel substrate 100 is etched to form therein through-holes 10 extending from the backside 100b to the tops of the conductive interconnects 110. The diameter (the average value) of the through-holes 10 varies depending on specific structure of the BSI image sensor, and for example, is approximately 10-100 μm. The through-holes 10 may be through silicon via (TSV) holes, which have a small footprint that is helpful in miniaturization of the BSI image sensor.

Subsequently, as shown in FIG. 3B, an isolation layer 101 is formed over side walls of the through-holes 10. In some embodiments, the isolation layer 101 may also cover a top surface of the insulating layer 120 (since the description hereof is based on the orientation with the backside 100b facing upward, the top surface of the insulating layer 120 is farther away from the conductive interconnects 110 than its bottom surface) and part of bottom surfaces of the through-holes 10. The isolation layer 101 may be made of, for example, silicon oxide.

Afterward, as shown in FIG. 3C, a metallic adhesion layer 102 is in geometric conformity over the top surface of the insulating layer 120, a surface of the isolation layer 101 and the bottom surfaces of the through-holes 10. The metallic adhesion layer 102 may be made of a material containing at least one of tungsten nitride and titanium nitride or another material. For example, the metallic adhesion layer 102 may be made of tungsten nitride or titanium nitride. The deposition may be accomplished by a CVD process, for example.

Thereafter, as shown in FIG. 3D, a conductive material 20 is deposited over the metallic adhesion layer 102 so as to fill up the through-holes 10. The height of the conductive material 20 exceeds the height of the through-hole 10. The conductive material 20 also cover a surface of the metallic adhesion layer 102 exclusive of the through-holes 10. The conductive material 20 may include tungsten, or be tungsten, for example. The deposition may be accomplished, for example, by a CVD process.

After that, as shown in FIG. 3E, a planarization (e.g., chemical mechanical polishing (CMP)) process is performed to remove the conductive material 20 and the metallic adhesion layer 102 above top edges of the through-holes 10 so that the conductive material 20 received in the through-holes 10 constitutes the conductive pillars 130. In alternative embodiments, the conductive material 20 and the metallic adhesion layer 102 above top edges of the through-holes 10 may be removed by etching, or by the combination of CMP and etching, or otherwise.

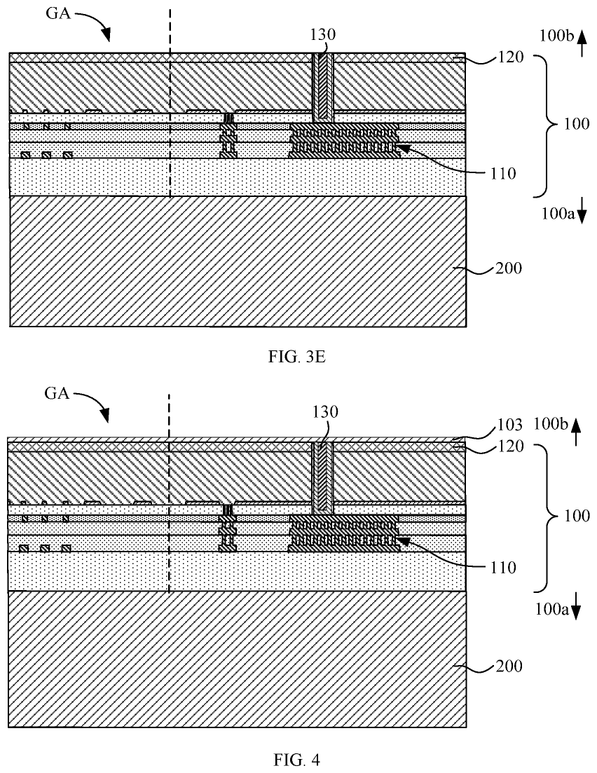

FIG. 4 is a schematic cross-sectional view of a structure after the titanium nitride layer is formed in the method according to an embodiment of the present application. Referring to FIG. 4, the second step described above is performed, in which the titanium nitride layer 103 is deposited by PVD process over the backside of the pixel substrate 100. The titanium nitride layer 103 covers the insulating layer 120. In case of the conductive pillars 130 having been already formed, in the second step, the titanium nitride layer 103 covers the surface that have undergone the planarization process and is in contact with the conductive pillars 130. Moreover, the titanium nitride layer 103 also covers the backside of the pixel substrate 100 exclusive of the conductive pillars 130, i.e., the titanium nitride layer 103 covers the top surface of the insulating layer 120. As an example, the PVD process for depositing the titanium nitride layer 103 uses a high purity titanium target (with a titanium purity of 99.999% or higher) and is performed at a DC power level of 6000-12000 W and a nitrogen flow rate of 50-100 sccm. The titanium nitride layer 103 has a thickness in the range of 130-500 Å, for example. Compared to a titanium nitride layer formed using a CVD process, the titanium nitride layer 103 formed by PVD process is denser in texture and has a better flatness, as the PVD process mainly deposited titanium with physical sputtering.

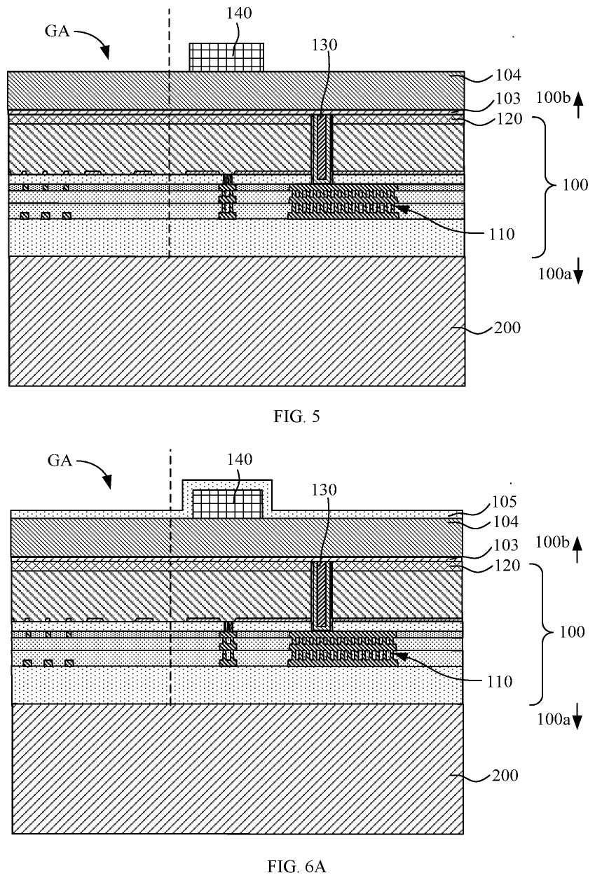

FIG. 5 is a schematic cross-sectional view of a structure after the formation of the tungsten film in the method according to an embodiment of the present application. Referring to FIG. 5, the third step described above is performed, in which the tungsten film 104 is deposited on the surface of the titanium nitride layer 103 by CVD process. Parameters of the CVD process for depositing the tungsten film 104 may be determined as needed. The tungsten film 104 covers the surface of the titanium nitride layer 103 away from the insulating layer 120. The tungsten film 104 may have a thickness depending on a design height of the tungsten grid. The tungsten film 104 over the conductive pillars 130 is electrically connected to the conductive interconnects 110 via the titanium nitride layer 103 and the conductive pillars 130.

Optionally, as shown in FIG. 5, after the tungsten film 104 is formed and before the fourth step is carried out, bonding pads 140 electrically connected to the conductive pillars 130 is formed on the tungsten film 104, and the bonding pads 140 are configured for connection with an external circuit. The formation of the bonding pads 140 may include depositing material (e.g., aluminum) for the bonding pads on the tungsten film 104 to form a layer of bonding pad material and patterning the layer of bonding pad material deposited using photolithography and etching processes well known in the art, thereby forming bonding pads 140. The bonding pads 140 are electrically connected to the conductive pillars 130 via the tungsten film 104 and the titanium nitride layer 103. In one embodiment, recesses (not shown) has been formed outside the grid area GA in advance in the backside 100b of the pixel substrate 100, and the insulating layer, the titanium nitride layer and the tungsten film are all in geometric conformity over surfaces of the recesses, with the bonding pads being formed in the respective recesses. Moreover, heights of the top surfaces of the bonding pads may be higher than height of the top surface of the tungsten film outside the recesses. This allows a reduced thickness of the resulting chip while ensuring performances of the bonding pads. This arrangement also helps in exposing only the pads and burying the tungsten film through the maskless etch back process after the subsequent covering of the protective layer.

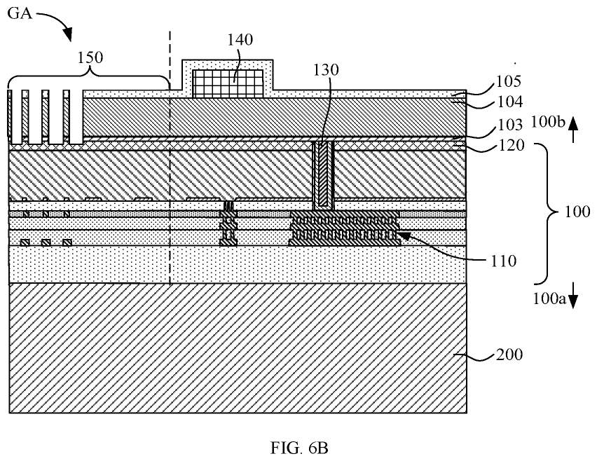

FIGS. 6A and 6B are schematic cross-sectional views showing the formation of the tungsten grid in the method according to an embodiment of the present application. Referring to FIGS. 6A and 6B, the fourth step described above is formed, in which the tungsten film 104 and the titanium nitride layer 103 are etched, thereby forming the tungsten grid on the backside 100b of the pixel substrate 100. As an example, the formation of the tungsten grid may include the steps below.

First of all, as shown in FIG. 6A, a protective layer 105 is formed on the tungsten film 104. The protective layer 105 may be, for example, in geometric conformity over the top and side surfaces of the bonding pads 140 and the exposed surface of the tungsten film 104. The protective layer may include at least one of silicon nitride, silicon oxynitride and silicon oxide.

Subsequently, as shown in FIG. 6B, a mask layer (not shown) is formed on the protective layer 105 and is then patterned using photolithography and etching processes. Using the pattern mask layer as a mask, the stack constructed of the protective layer 105, the tungsten film 104 and the titanium nitride layer 103 is etched so that the tungsten grid 150 is formed on the backside 100b of the pixel substrate 100, followed by the removal of the mask layer. The mask layer may be either a single-layer or multi-layer structure. For example, it may be a photoresist layer or a stack constructed of an anti-reflective layer and a photoresist layer.

During the etching process for forming the tungsten grid 150, portions of the tungsten film 104 and the underlying titanium nitride layer 103 are etched through and thus is removed in accordance with a designed pattern of the tungsten grid, and the remainder thereof defines lines of the tungsten grid 150 in the grid area GA. More specifically, lines of the tungsten grid 150 may lie in inter-pixel gaps in the pixel region, and for the grid area GA outside the pixel region, lines of the tungsten grid 150 may be arranged as required in the regions where optical darkness is required. As is described above, in one embodiment, the insulating layer 120 includes, stacked one on another from the backside 110b in a direction away from the front side 110a, a high-k material film, a bottom oxide film, a nitride film and a top oxide film. For the insulating layer 120 with such a structure, when the photolithography and etching processes are performed to form the tungsten grid 150, the top oxide film and the nitride film in the insulating layer 120 are patterned while the high-k material film and the bottom oxide film in the insulating layer 120 are retained, so as to avoid damages to the pixel substrate 100 by the etching process. However, the present application is not so limited because in other embodiments, the insulating layer 120 may be otherwise structured and not etched.

After the tungsten grid 150 is formed, a dielectric material may be subsequently deposited in gaps between lines of the tungsten grid 150 and over the tungsten grid 150 and the bonding pad 140 is kept exposed (while the tungsten film 104 is not exposed). This can be achieved using any suitable method known in the art, and a detailed description thereof is omitted herein.

As a result of the above steps, the tungsten grid 150 is formed on the backside 100b of the pixel substrate 100. The PVD-deposited titanium nitride layer 103 provides a tungsten growth surface with extremely low roughness, and the tungsten film 104 is subsequently deposited on the titanium nitride layer 103 by CVD. Both the tungsten film 104 and the titanium nitride layer 103 are then etched, resulting in the formation of the tungsten grid 150. Since the tungsten growth surface is sufficiently flat, crystalline grains of tungsten in the tungsten film are relatively small, which enables the tungsten film to have a good uniformity and a superior flatness and allows to mitigate the risk of tungsten loss due to the occurrence of inter-crystalline corrosions during etching. Thus, the resulting tungsten grid has an improved flatness and an optimized morphology, which are helpful in enhancing optical performances of the BSI image sensors.

Embodiments of the present application also relate to a BSI image sensor that is is formed using the above described method, in which the tungsten grid 150 contains relatively small tungsten crystals and the tungsten film owns good uniformity and flatness as well as a reduced risk of tungsten loss. That is, the tungsten grid 150 has a good morphology and quality, which are helpful in obtaining good optical performance. Referring to FIG. 6B, the BSI image sensor includes:

a pixel substrate 100 having a front side 100a and an opposing backside 100b, the pixel substrate comprising conductive interconnects formed on the front side, an insulating layer formed on the backside, a plurality of light sensitive pixels configured to sense radiation that enters the pixel substrate from the backside thereof, and a grid area GA;

conductive pillars 130 arranged outside the grid area GA, the conductive pillar 130 extending through the pixel substrate 100 and having one end electrically connected to the conductive interconnects 110 and the other end connected to a titanium nitride layer 103, the titanium nitride layer 103 having a surface away from the conductive pillars 130 covered by a tungsten film, each of the titanium nitride layer 103 and the tungsten film 104 extending to the grid area;

bonding pads 140 arranged outside the grid area GA, the bonding pads 140 disposed on a surface of the tungsten film 104 away from the titanium nitride layer 103, the bonding pads 140 electrically connected to the conductive pillars 130 via the tungsten film 104 and the titanium nitride layer 103; and

a tungsten grid 150 arranged within the grid area GA, the tungsten grid 150 including the titanium nitride layer 103 and the tungsten film 104, which are stacked from the backside 110b in a direction away from the front side 110a.

Noted that the embodiments disclosed herein are described in a progressive manner, with the description of each embodiment focusing on its differences from others. Reference can be made between the embodiments for their identical or similar parts. Since the BSI image sensor embodiments correspond to the method embodiments, they are described relatively briefly, and reference can be made to the is BSI image sensor embodiments for details in them.

While several preferred embodiments of present application has been described above, they are not intended to limit the protection scope of present application in any way. Any person skilled in the art without departing from the spirit and scope of the present application can make possible changes and modifications to the technical solution of present application by using the foregoing methods and technical content. Accordingly, any and all such simple variations, equivalent alternatives and modifications made to the foregoing embodiments without departing from the scope of the present application are intended to fall within the scope thereof

What is claimed is:

1. A method of forming a backside illuminated (BSI) image sensor, comprising:
providing a pixel substrate having a front side and an opposing backside, the pixel substrate comprising a plurality of conductive interconnects formed on the front side, an insulating layer formed on the backside and a plurality of light sensitive pixels configured to sense radiation that enters the pixel substrate from the backside;
depositing a titanium nitride layer over the backside of the pixel substrate using a physical vapor deposition (PVD) process, the titanium nitride layer covering the insulating layer;
depositing a tungsten film on a surface of the titanium nitride layer using a chemical vapor deposition (CVD) process; and
etching the tungsten film and the titanium nitride layer to form a tungsten grid on the backside of the pixel substrate.

2. The method of claim 1, wherein the PVD process for depositing the titanium nitride layer uses a target having a titanium purity of 99.999% or higher and is performed at a DC power level of 6000-12000 W and a nitrogen flow rate of 50-100 sccm.

3. The method of claim 1, wherein the titanium nitride layer has a thickness of 130-500 Å.

4. The method of claim 1, further comprising, prior to the deposition of the titanium nitride layer:
etching the pixel substrate to form therein a plurality of through-holes extending from the backside to tops of the plurality of conductive interconnects;
forming an isolation layer over side walls of the through-holes;
forming a metallic adhesion layer, which is in geometric conformity over a top surface of the insulating layer, a surface of the isolation layer and bottoms of the through-holes;
depositing a conductive material on the metallic adhesion layer, wherein the deposited conductive material completely fills the through-holes and further covers a surface of the metallic adhesion layer; and
removing the conductive material and the metallic adhesion layer above top edges of the through-holes using a planarization process, the conductive material received in the through-holes constituting conductive pillars,
wherein after the titanium nitride layer is deposited, the titanium nitride layer is in contact with the conductive pillars.

5. The method of claim 4, wherein the metallic adhesion layer is made of a material containing at least one of tungsten nitride and titanium nitride, and the conductive pillars are made of a material containing tungsten.

6. The method of claim 5, wherein the metallic adhesion layer and the conductive material are deposited using CVD processes.

7. The method of claim 4, after the tungsten film is formed and before the tungsten film and the titanium nitride layer are etched, further comprising:
forming a bonding pad material layer on the tungsten film; and
etching the bonding pad material layer to form bonding pads that are electrically connected to the conductive pillars via the tungsten film and the titanium nitride layer.

8. The method of claim 1, wherein etching the tungsten film and the titanium nitride layer to form the tungsten grid on the backside of the pixel substrate comprises:
forming a protective layer on the tungsten film, the protective layer covering an exposed surface of the tungsten film; and
forming a mask layer on the protective layer, patterning the mask layer using photolithography and etching processes and etching a stack constituted by the protective layer, the tungsten film and the titanium nitride layer using the patterned mask layer as a mask, thereby forming the tungsten grid on the backside of the pixel substrate.

9. The method of claim 8, wherein the insulating layer comprises, stacked one on another from the backside in a direction away from the front side, a high-k material film, a bottom oxide film, a nitride film and a top oxide film, and wherein the top oxide film and the nitride film in the insulating layer are also patterned when the stack constituted by the protective layer, the tungsten film and the titanium nitride layer is etched to form the tungsten grid.

10. A backside illuminated (BSI) image sensor formed using the method of claim 1, wherein the BSI image sensor comprises:
a pixel substrate having a front side and an opposing backside, the pixel substrate comprising a plurality of conductive interconnects formed on the front side, an insulating layer formed on the backside, a plurality of light sensitive pixels configured to sense radiation that enters the pixel substrate from the backside, and a grid area;
a plurality of conductive pillars arranged outside the grid area, each of the plurality of conductive pillars extending through the pixel substrate and having one end electrically connected to a corresponding one of the plurality of conductive interconnects and the other end connected to a titanium nitride layer, the titanium nitride layer having a surface away from the conductive pillars covered by a tungsten film, each of the titanium nitride layer and the tungsten film extending to the grid area;
bonding pads arranged outside the grid area, the bonding pads disposed on a surface of the tungsten film away from the titanium nitride layer, the bonding pads electrically connected to the conductive pillars via the tungsten film and the titanium nitride layer; and
a tungsten grid arranged within the grid area, the tungsten grid comprising the titanium nitride layer and the tungsten film, which are stacked from the backside in a direction away from the front side.

11. The backside illuminated (BSI) image sensor of claim 10, wherein each of the plurality of conductive interconnects comprises a plurality of patterned conductive layers isolated by a dielectric material, and a plurality of conductive plugs.

12. The method of claim 1, wherein the pixel substrate is thinned from the backside before the insulating layer is formed on the backside.

13. The method of claim 8, wherein etching the stack constituted by the protective layer, the tungsten film and the titanium nitride layer comprises etching through portions of the tungsten film and the titanium nitride layer, and remaining portions of the tungsten film and the titanium nitride layer, thereby defining lines of the tungsten grid.

14. The method of claim 13, after the formation of the tungsten grid, further comprising depositing a dielectric material in gaps between lines of the tungsten grid and over the tungsten grid.
